(19) United States
(12) Patent Application Publication
(10) Pub. No.: US 2024/0250195 A1
(43) Pub. Date: Jul. 25, 2024

(54) PHOTOVOLTAIC SHINGLES WITH TANDEM SOLAR CELLS

(71) Applicant: GAF Energy LLC, Parsippany, NJ (US)

(72) Inventor: Gabriela Bunea, San Jose, CA (US)

(21) Appl. No.: 18/420,336

(22) Filed: Jan. 23, 2024

Related U.S. Application Data
(60) Provisional application No. 63/481,300, filed on Jan. 24, 2023.

(51) Int. Cl. H01L 31/049; H01L 31/048; H02S 20/25

(52) U.S. Cl. CPC H01L 31/049; H02S 20/25; H01L 31/0481

(57) ABSTRACT

A system includes a plurality of photovoltaic shingles, each of which includes a photovoltaic layer having at least one solar cell and at least one electrical conductor electrically connector the solar cell. The at least one electrical conductor extends from a first end of the photovoltaic layer. Each of the photovoltaic shingles includes an encapsulant encapsulating the solar cell, a front sheet having a first glass layer, and a backsheet. The first end of the at least one electrical conductor is between first and second ends of the backsheet.

### CROSS-REFERENCE TO RELATED APPLICATION

This application is a Section 111(a) application relating to and claiming the benefit of commonly owned, co-pending U.S. Provisional Patent Application Ser. No. 63/481,300, filed Jan. 24, 2023, entitled “PHOTOVOLTAIC SHINGLES WITH TANDEM SOLAR CELLS,” the contents of each of which are incorporated herein by reference in its entirety.

### FIELD OF THE INVENTION

The present invention relates to photovoltaic shingles and, more particularly, photovoltaic shingles with tandem solar cells.

### BACKGROUND

Photovoltaic systems are installed on building roofs to generate electricity.

### SUMMARY

In some embodiments, a system includes a plurality of photovoltaic shingles installed on a roof deck, wherein each of the photovoltaic shingles includes a photovoltaic layer, wherein the photovoltaic layer includes at least one solar cell, a first end, and at least one electrical conductor, wherein the at least one electrical conductor is electrically connected to the at least one solar cell, wherein the at least one electrical conductor extends from the first end, and wherein the at least one electrical conductor includes a first end; an encapsulant encapsulating the at least one solar cell, wherein the encapsulant includes a first surface and a second surface opposite the first surface, a frontsheet juxtaposed with the first surface of the encapsulant, wherein the frontsheet includes a first glass layer; and a backsheet under the second surface of the encapsulant, wherein the backsheet includes a first end and a second end opposite the first end of the backsheet, and wherein the first end of the at least one electrical conductor is between the first end of the backsheet and the second end of the backsheet.

In some embodiments, each of the plurality of photovoltaic shingles includes a second glass layer, wherein the second glass layer is between the second surface of the encapsulant and the backsheet. In some embodiments, the backsheet is composed of a polymer. In some embodiments, the backsheet is composed of thermoplastic polyolefin (TPO). In some embodiments, the backsheet includes asphalt. In some embodiments, each of the plurality of photovoltaic shingles includes a first adhesive layer, wherein the backsheet is attached to the second glass layer by the first adhesive layer. In some embodiments, the frontsheet includes a polymer layer having a first surface and a second surface opposite the first surface of the polymer layer, wherein the second surface of the polymer layer is attached to the first glass layer. In some embodiments, the polymer layer includes a first end and a second end opposite the first end of the polymer layer, and wherein the first end of the at least one electrical conductor is between the first end of the polymer layer and the second end of the polymer layer. In some embodiments, the first end of the polymer layer is substantially aligned with the first end of the backsheet. In some embodiments, the polymer layer includes ethylene tetrafluoroethylene (ETFE).

In some embodiments, the at least one solar cell is a tandem solar cell. In some embodiments, the at least one electrical conductor includes a plurality of electrical conductors. In some embodiments, the tandem solar cell is a two-conductor tandem solar cell, and wherein the plurality of electrical conductors includes two electrical conductors. In some embodiments, the tandem solar cell is a four-conductor tandem solar cell, and wherein the plurality of electrical conductors includes four electrical conductors.

In some embodiments, each of the plurality of photovoltaic shingles includes a bracket having a first end and a second end opposite the first end of the bracket, and wherein the first glass layer includes a first end, wherein the second end of the bracket is attached to the first end of the first glass layer. In some embodiments, the first end of the at least one electrical conductor is between the first end of the bracket and the first end of the first glass layer. In some embodiments, the bracket is attached to the first glass layer by an adhesive. In some embodiments, the bracket is made from an electrical insulating material. In some embodiments, each of the first glass layer and the second glass layer has a thickness of 0.5 mm to 3 mm.

In some embodiments, a photovoltaic shingle includes a photovoltaic layer, wherein the photovoltaic layer includes at least one solar cell, a first end, and at least one electrical conductor, wherein the at least one electrical conductor is electrically connected to the at least one solar cell, wherein the at least one electrical conductor extends from the first end, and wherein the at least one electrical conductor includes a first end; an encapsulant encapsulating the at least one solar cell, wherein the encapsulant includes a first surface and a second surface opposite the first surface, a frontsheet juxtaposed with the first surface of the encapsulant, wherein the frontsheet includes a first glass layer; and a backsheet under the second surface of the encapsulant, wherein the backsheet includes a first end and a second end opposite the first end of the backsheet, and wherein the first end of the at least one electrical conductor is between the first end of the backsheet and the second end of the backsheet.

### BRIEF DESCRIPTION OF THE DRAWINGS

FIGS. 1A and 1B are a top plan view and a side elevational view, respectively, of some embodiments of a photovoltaic shingle;

FIG. 2 is a schematic, side elevational view of some embodiments of a photovoltaic shingle;

FIGS. 3A and 3B are schematic, side elevational view of some embodiments of a solar cell;

FIG. 4 is a schematic, side elevational view of some embodiments of a photovoltaic shingle;

FIG. 5 is a schematic, side elevational view of some embodiments of a photovoltaic shingle;

FIG. 6 is a schematic, side elevational view of some embodiments of a photovoltaic shingle; and

FIG. 7 is a top perspective view of some embodiments of a roofing system including some embodiments of a plurality of photovoltaic shingles.

### DETAILED DESCRIPTION

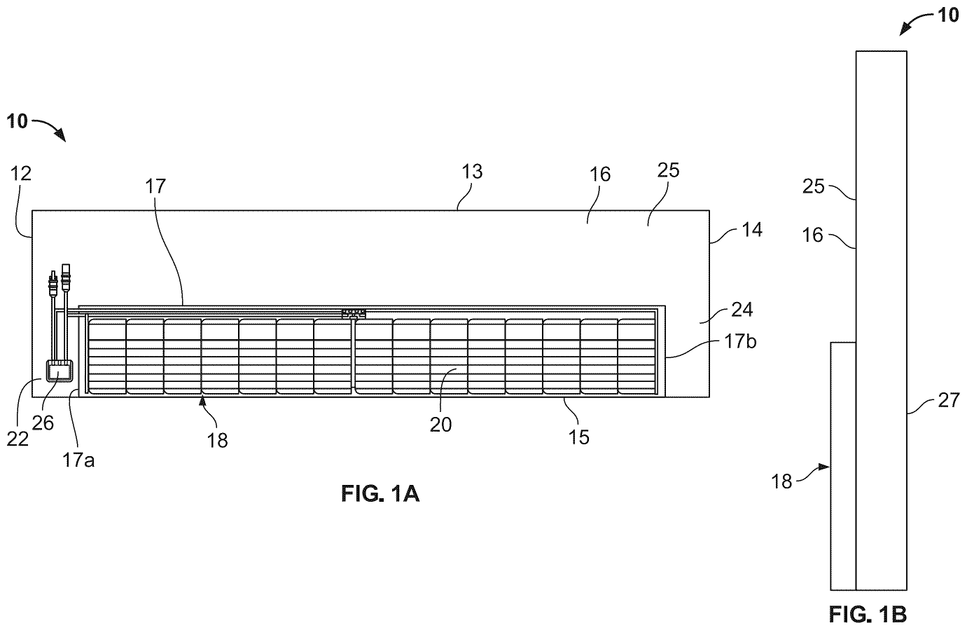

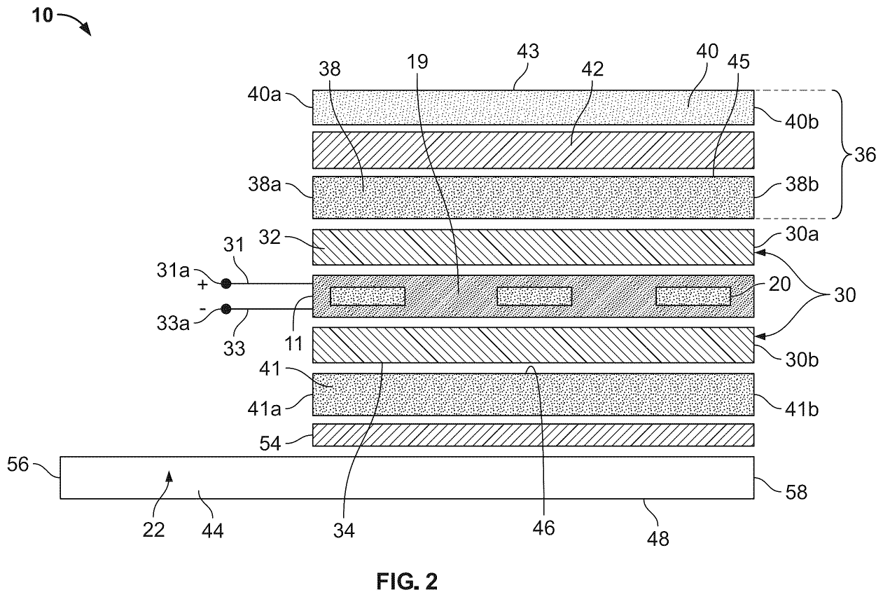

Referring to FIGS. 1A, 1B and 2, in some embodiments, a photovoltaic shingle 10 includes a first end 12, a second end 14 opposite the first end 12, a first edge 13 extending from the first end 12 to the second end 14, and a second edge 15 opposite the first edge 13 and extending from the first end 12 to the second end 14. In some embodiments, the photovoltaic shingle 10 includes a headlap portion 16. In some embodiments, the headlap portion 16 extends from the first end 12 to the second end 14 and from the first edge 13 to a first location 17 between the first edge 13 and the second edge 15. In some embodiments, the photovoltaic shingle 10 includes a reveal portion 18. In some embodiments, the reveal portion 18 includes a photovoltaic layer 19. In some embodiments, the photovoltaic layer 19 includes a first end 11 and at least one solar cell 20. In some embodiments, the photovoltaic shingle 10 includes a first side lap 22 located at the first end 12. In some embodiments, the first side lap 22 includes a length extending from the first end 12 to a second location 17a between the first end 12 and the second end 14. In some embodiments, the photovoltaic shingle 10 includes a second side lap 24 located at the second end 14. In some embodiments, the second side lap 24 includes a length extending from the second end 14 to a third location 17b between the first end 12 and the second end 14. In some embodiments, the photovoltaic shingle 10 includes an outer surface 25 and an inner surface 27 opposite the outer surface 25. In some embodiments, the reveal portion 18 extends from the first side lap 22 to the second side lap 24 and from the second edge 15 to the first location 17. In some embodiments, the photovoltaic shingle 10 is configured to be installed on a building structure. In some embodiments, the photovoltaic shingle 10 is configured to be installed on an exterior wall of a building structure as described in further detail below. In some embodiments, at least one junction box 26 is located on the first side lap 22. In some embodiments, the at least one junction box 26 includes a plurality of the junction boxes 26. In certain embodiments, other electronic and electrical components may be attached to the first side lap 22. In certain embodiments, the electronic and electrical components are embedded within the first side lap 22. In some embodiments, non-limiting examples of such electronic and electrical components include an electrical connector, a rapid shutdown device, an optimizer, and an inverter. In some embodiments, the at least one junction box 26 includes an optimizer. In some embodiments, the photovoltaic shingle 10 includes a structure, composition, components, and/or function similar to those of one or more embodiments of the photovoltaic shingles disclosed in PCT International Patent Publication No. WO 2022/051593, Application No. PCT/US2021/049017, published Mar. 10, 2022, entitled Building Integrated Photovoltaic System, owned by GAF Energy LLC, the contents of which are incorporated by reference herein in its entirety.

In some embodiments, the at least one solar cell 20 includes a plurality of the solar cells 20. In some embodiments, the plurality of solar cells 20 includes two solar cells. In some embodiments, the plurality of solar cells 20 includes three solar cells. In some embodiments, the plurality of solar cells 20 includes four solar cells. In some embodiments, the plurality of solar cells 20 includes five solar cells. In some embodiments, the plurality of solar cells 20 includes six solar cells. In some embodiments, the plurality of solar cells 20 includes seven solar cells. In some embodiments, the plurality of solar cells 20 includes eight solar cells. In some embodiments, the plurality of solar cells 20 includes nine solar cells. In some embodiments, the plurality of solar cells 20 includes ten solar cells. In some embodiments, the plurality of solar cells 20 includes eleven solar cells. In some embodiments, the plurality of solar cells 20 includes twelve solar cells. In some embodiments, the plurality of solar cells 20 includes thirteen solar cells. In some embodiments, the plurality of solar cells 20 includes fourteen solar cells. In some embodiments, the plurality of solar cells 20 includes fifteen solar cells. In some embodiments, the plurality of solar cells 20 includes sixteen solar cells. In some embodiments, the plurality of solar cells 20 includes more than sixteen solar cells.

In some embodiments, the plurality of solar cells 20 is arranged in one row (i.e., one reveal). In another embodiment, the plurality of solar cells 20 is arranged in two rows (i.e., two reveals). In another embodiment, the plurality of solar cells 20 is arranged in three rows (i.e., three reveals). In another embodiment, the plurality of solar cells 20 is arranged in four rows (i.e., four reveals). In another embodiment, the plurality of solar cells 20 is arranged in five rows (i.e., five reveals). In another embodiment, the plurality of solar cells 20 is arranged in six rows (i.e., six reveals). In other embodiments, the plurality of solar cells 20 is arranged in more than six rows. In some embodiments, the at least one solar cell 20 is electrically inactive (i.e., a “dummy” solar cell). In some embodiments, the at least one solar cell 20 is a crystalline silicon (c-Si) cell.

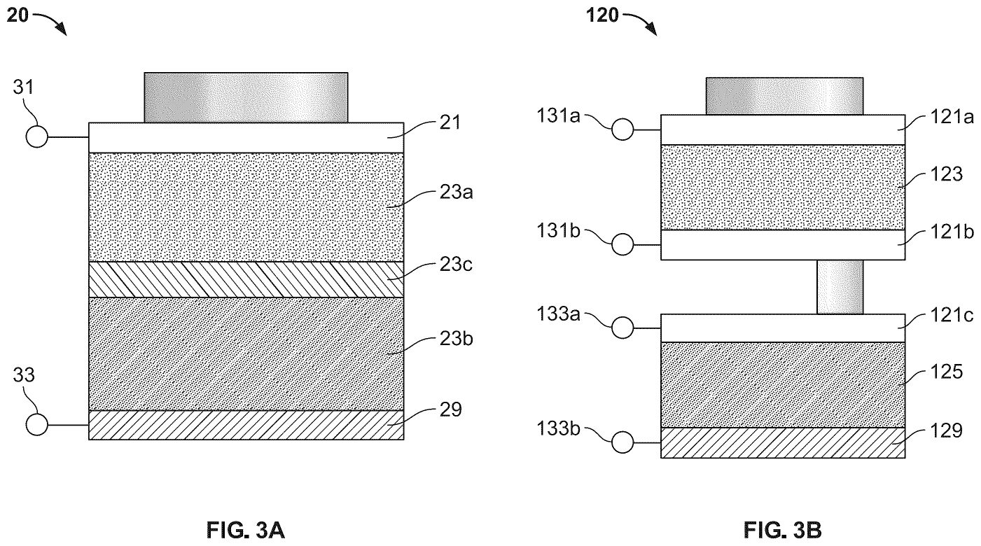

Referring to FIGS. 2 and 3A, in some embodiments, the at least one solar cell 20 is a tandem solar cell. In some embodiments, the at least one solar cell 20 is a two (2) terminal tandem cell. In some embodiments, the at least one solar cell 20 includes an electrode 21, a top cell 23a under the electrode 21, a bottom cell 23b under the top cell 23a, a junction layer 23c between the top cell 23a and the bottom cell 23b, and a back reflector 29 under the bottom cell 23b. In some embodiments, the at least one solar cell 20 includes a first electrical conductor 31. In some embodiments, the at least one solar cell 20 includes a second electrical conductor 33. In some embodiments, each of the first electrical conductor 31 and the second electrical conductor 33 is an electrical terminal. In some embodiments, each of the first electrical conductor 31 and the second electrical conductor 33 is an electrical wire or cable. In some embodiments, each of the first electrical conductor 31 and the second electrical conductor 33 is an electrical bussing. In some embodiments, each of the first electrical conductor 31 and the second electrical conductor 33 is an electrical ribbon bussing. In some embodiments, the first electrical conductor 31 includes an electrical connector. In some embodiments, the second electrical conductor 33 includes an electrical connector. In some embodiments, the first electrical conductor 31 is electrically connected to the electrode 21. In some embodiments, the first electrical conductor 31 is a positive electrical conductor. In some embodiments, the second electrical conductor 33 is a negative electrical conductor. In some embodiments, the second electrical conductor 33 is electrically connected to the back reflector 29. In some embodiments, the second electrical conductor 33 is a positive electrical conductor. In some embodiments, the second electrical conductor 33 is a negative electrical conductor. In some embodiments, the electrode 21 is transparent. In some embodiments, the electrode 21 is translucent. In some embodiments, the top cell 23a is a perovskite cell. In some embodiments, the bottom cell 23b is a silicon cell. In some embodiments, the top cell 23a is a gallium arsenide (GaAs) cell.

In some embodiments, the first electrical conductor 31 extends from the first end 11 of the photovoltaic layer 19. In some embodiments, the second electrical conductor 33 extends from the first end 11 of the photovoltaic layer 19. In some embodiments, the first electrical conductor 31 includes a first end 31a. In some embodiments, the second electrical conductor 33 includes a first end 33a. In some embodiments, the first electrical conductor 31 includes an electrical connector at the first end 31a. In some embodiments, the second electrical conductor 33 includes an electrical connector at the first end 33a.

Referring to FIG. 3B, in some embodiments, at least one solar cell 120 is a four (4) terminal tandem cell. In some embodiments, the at least one solar cell 120 includes a first electrode 121a, a second electrode 121b, and a top cell 123 between the first electrode 121a and the second electrode 121b. In some embodiments, the at least one solar cell 120 includes a third electrode 121c, a back reflector 129, and a bottom cell 125 between the third electrode 121c and the back reflector 129. In some embodiments, the at least one solar cell 120 includes a first electrical conductor 131a and a second electrical conductor 131b. In some embodiments, the first electrical conductor 131a is electrically connected to the first electrode 121a. In some embodiments, the second electrical conductor 131b is electrically connected to the second electrode 121b. In some embodiments, the at least one solar cell 120 includes a third electrical conductor 133a and a fourth electrical conductor 133b. In some embodiments, the third electrical conductor 133a is electrically connected to the third electrode 121c. In some embodiments, the fourth electrical conductor 133b is electrically connected to the back reflector 129. In some embodiments, the first electrical conductor 131a is a positive electrical conductor. In some embodiments, the first electrical conductor 131a is a negative electrical conductor. In some embodiments, the second electrical conductor 131b is a positive electrical conductor. In some embodiments, the second electrical conductor 131b is a negative electrical conductor. In some embodiments, the third electrical conductor 133a is a positive electrical conductor. In some embodiments, the third electrical conductor 133a is a negative electrical conductor. In some embodiments, the fourth electrical conductor 133b is a positive electrical conductor. In some embodiments, the fourth electrical conductor 133b is a negative electrical conductor. In some embodiments, each of the electrical conductors 131a, 131b, 133a, 133b is an electrical wire or cable. In some embodiments, each of the electrical conductors 131a, 131b, 133a, 133b is an electrical bussing. In some embodiments, each of the electrical conductors 131a, 131b, 133a, 133b is an electrical ribbon bussing. In some embodiments, each of the electrical conductors 131a, 131b, 133a, 133b includes an electrical connector. In some embodiments, each of the electrodes 121a, 121b, 121c is transparent. In some embodiments, each of the electrodes 121a, 121b, 121c is translucent. In some embodiments, the top cell 123 is a perovskite cell. In some embodiments, the bottom cell 125 is a silicon cell. In some embodiments, the top cell 123 and the bottom cell 125 are separate portions of the solar cell 20. In some embodiments, the second electrode 121b is separated from the third electrode 121c by a distance D.

Referring to FIG. 2, in some embodiments, the photovoltaic shingle 10 includes an encapsulant 30 encapsulating the at least one solar cell 20. In some embodiments, the encapsulant 30 includes a first layer 30a having a first surface 32 and a second layer 30b having a second surface 34 opposite the first surface 32. In some embodiments, the photovoltaic shingle 10 includes a frontsheet 36 juxtaposed with the first surface 32 of the first layer 30a of the encapsulant 30. In some embodiments, the frontsheet 36 includes a first glass layer 38. In some embodiments, the first glass layer 38 includes a first end 38a and a second end 38b opposite the first end 38a.

In some embodiments, the first glass layer 38 has a thickness of 0.5 mm to 3 mm. In some embodiments, the first glass layer 38 has a thickness of 0.5 mm to 2.5 mm. In some embodiments, the first glass layer 38 has a thickness of 0.5 mm to 2 mm. In some embodiments, the first glass layer 38 has a thickness of 0.5 mm to 1.5 mm. In some embodiments, the first glass layer 38 has a thickness of 0.5 mm to 1 mm. In some embodiments, the first glass layer 38 has a thickness of 1 mm to 3 mm. In some embodiments, the first glass layer 38 has a thickness of 1 mm to 2.5 mm. In some embodiments, the first glass layer 38 has a thickness of 1 mm to 2 mm. In some embodiments, the first glass layer 38 has a thickness of 1 mm to 1.5 mm. In some embodiments, the first glass layer 38 has a thickness of 1.5 mm to 3 mm. In some embodiments, the first glass layer 38 has a thickness of 1.5 mm to 2.5 mm. In some embodiments, the first glass layer 38 has a thickness of 1.5 mm to 2 mm. In some embodiments, the first glass layer 38 has a thickness of 2 mm to 3 mm. In some embodiments, the first glass layer 38 has a thickness of 2 mm to 2.5 mm.

In some embodiments, the first glass layer 38 has a thickness of 2.5 mm to 3 mm. In some embodiments, the first glass layer 38 has a thickness of 0.5 mm. In some embodiments, the first glass layer 38 has a thickness of 1 mm. In some embodiments, the first glass layer 38 has a thickness of 1.5 mm. In some embodiments, the first glass layer 38 has a thickness of 2 mm. In some embodiments, the first glass layer 38 has a thickness of 2.5 mm. In some embodiments, the first glass layer 38 has a thickness of 3 mm.

In some embodiments, the frontsheet 36 includes a polymer layer 40 attached to the first glass layer 38. In some embodiments, the polymer layer 40 forms an upper surface of the photovoltaic shingle 10. In some embodiments, the polymer layer 40 includes a first end 40a and a second end 40b opposite the first end 40a.

In some embodiments, the polymer layer 40 is composed of a fluoropolymer. In certain embodiments, the fluoropolymer may be ethylene tetrafluoroethylene (ETFE), fluoropolymer is polyvinylidene fluoride (PVDF), tetrafluoroethylene-hexafluoropropylene copolymers (FEP), and tetrafluoroethylene-hexafluoropropylene-vinylidene fluoride copolymers (THV), polyvinyl fluoride (PVF), or blends thereof. In some embodiments, the frontsheet is composed of fluoropolymers, acrylics, polyesters, silicones, polycarbonates, or combinations thereof. In some embodiments, the polymer layer 40 is composed of polyethylene terephthalate (PET), polyethylene naphthalate (PEN), polyetheretherketone (PEEK), polyaryletherketone (PAEK), polyarylate (PAR), polyetherimide (PEI), polyarylsulfone (PAS), polyethersulfone (PES), polyamideimide (PAI), polyphenylsulfone (PPSU), polyolefin, cyclic olefin copolymers (CPCs), or polyimide. In some embodiments, the polymer layer 40 is composed of a crosslinked polymeric material. In some embodiments, 50% to 99% of the polymer chains of the polymeric material are crosslinked.

In some embodiments, the polymer layer 40 is attached to the first glass layer 38 by a first adhesive layer 42. In some embodiments, the first adhesive layer 42 may include polyvinyl butyrate, acrylic, silicone, or polycarbonate. In some embodiments, the first adhesive layer 42 may include pressure sensitive adhesives. In some embodiments, the polymer layer 40 is attached to the first glass layer 38 by thermal bonding. In some embodiments, the first adhesive layer 42 is transparent. As used herein, the term “transparent” means having a solar weighted transmittance of 80% or greater, and with respect to certain embodiments of the photovoltaic shingle 10, a transparent layer of the photovoltaic shingle has a solar weighted transmittance of 80% or greater.

In some embodiments, an upper surface 43 of the polymer layer 40 is an upper surface of the photovoltaic shingle 10. In some embodiments, the upper surface 43 of the polymer layer 40 is textured. In some embodiments, the upper surface 43 of the polymer layer 40 is embossed. In some embodiments, the upper surface 43 of the polymer layer 40 is embossed with a plurality of indentations. In some embodiments, the upper surface 43 of the polymer layer 40 includes a pattern. In some embodiments, the upper surface 43 of the polymer layer 40 includes a printed pattern. In some embodiments, the upper surface 43 of the polymer layer 40 includes an embossed pattern. In some embodiments, the upper surface 43 of the polymer layer 40 includes a textured pattern.

In some embodiments, the frontsheet 36 does not include the polymer layer 40 or the first adhesive layer 42. In some embodiments, an upper surface 45 of the first glass layer 38 is an upper surface of the photovoltaic shingle 10. In some embodiments, the upper surface 45 of the first glass layer 38 is textured. In some embodiments, the upper surface 45 of the first glass layer 38 is embossed. In some embodiments, the upper surface 45 of the first glass layer 38 is embossed with a plurality of indentations. In some embodiments, the upper surface 45 of the first glass layer 38 includes a pattern. In some embodiments, the upper surface 45 of the first glass layer 38 includes a printed pattern. In some embodiments, the upper surface 45 of the first glass layer 38 includes an embossed pattern. In some embodiments, the upper surface 45 of the first glass layer 38 includes a textured pattern.

In some embodiments, the photovoltaic shingle 10 includes a second glass layer 41. In some embodiments, the second glass layer 41 includes a first end 41a and a second end 41b opposite the first end 41a. In some embodiments, the second glass layer 41 is juxtaposed with the second surface 34 of the second layer 30b of the encapsulant 30. In some embodiments, the second glass layer 41 includes a size, structure and/or composition similar to those of the first glass layer 38.

In some embodiments, the second glass layer 41 has a thickness of 0.5 mm to 3 mm. In some embodiments, the second glass layer 41 has a thickness of 0.5 mm to 2.5 mm. In some embodiments, the second glass layer 41 has a thickness of 0.5 mm to 2 mm. In some embodiments, the second glass layer 41 has a thickness of 0.5 mm to 1.5 mm. In some embodiments, the second glass layer 41 has a thickness of 0.5 mm to 1 mm. In some embodiments, the second glass layer 41 has a thickness of 1 mm to 3 mm. In some embodiments, the second glass layer 41 has a thickness of 1 mm to 2.5 mm. In some embodiments, the second glass layer 41 has a thickness of 1 mm to 2 mm. In some embodiments, the second glass layer 41 has a thickness of 1 mm to 1.5 mm. In some embodiments, the second glass layer 41 has a thickness of 1.5 mm to 3 mm. In some embodiments, the second glass layer 41 has a thickness of 1.5 mm to 2.5 mm. In some embodiments, the second glass layer 41 has a thickness of 1.5 mm to 2 mm. In some embodiments, the second glass layer 41 has a thickness of 2 mm to 3 mm. In some embodiments, the second glass layer 41 has a thickness of 2 mm to 2.5 mm. In some embodiments, the second glass layer 41 has a thickness of 2.5 mm to 3 mm. In some embodiments, the second glass layer 41 has a thickness of 0.5 mm. In some embodiments, the second glass layer 41 has a thickness of 1 mm. In some embodiments, the second glass layer 41 has a thickness of 1.5 mm. In some embodiments, the second glass layer 41 has a thickness of 2 mm. In some embodiments, the second glass layer 41 has a thickness of 2.5 mm. In some embodiments, the second glass layer 41 has a thickness of 3 mm.

In some embodiments, the photovoltaic shingle 10 includes a backsheet 44. In some embodiments, the backsheet 44 is juxtaposed with the second glass layer 41. In some embodiments, the backsheet 44 includes a first surface 46 and a second surface 48 opposite the first surface 46 of the backsheet 44. In some embodiments, the second surface 48 of the backsheet 44 forms a lower surface of the photovoltaic shingle 10. In some embodiments, the backsheet 44 is attached to the second glass layer 41 by a second adhesive layer 54. In some embodiments, the backsheet 44 includes only one, single layer. In some embodiments, the backsheet 44 includes a second layer. In some embodiments, the backsheet 44 includes at least two layers. In some embodiments, the backsheet 44 does not include the second layer.

In some embodiments, the backsheet 44 is composed of a polymeric material. In some embodiments, the backsheet 44 is composed of polyethylene terephthalate (“PET”). In some embodiments, the backsheet 44 is composed of ethylene tetrafluoroethylene (“ETFE”). In some embodiments, the backsheet 44 is composed of an acrylic such as polymethyl methacrylate (“PMMA”). In some embodiments, the backsheet 44 is composed of thermoplastic polyolefin (TPO). In some embodiments, the backsheet 44 includes of a single ply TPO roofing membrane. In some embodiments, non-limiting examples of TPO membranes are disclosed in U.S. Pat. No. 9,359,014 to Yang et al., which is incorporated by reference herein in its entirety. In some embodiments, the backsheet 44 is composed of polyvinyl chloride (PVC). In some embodiments, the backsheet 44 is composed of ethylene propylene diene monomer (EPDM) rubber. In some embodiments, the backsheet 44 is a polymeric material composed of recycled rubber. In some embodiments, the backsheet 44 is a polymeric material composed of modified bitumen. In some embodiments, the backsheet 44 is a polymeric material composed of asphalt. In some embodiments, the backsheet 44 is composed of asphalt. In some embodiments, the backsheet 44 is a polymeric material composed of a non-asphalt (NAS) roofing material. In some embodiments, In some embodiments, the backsheet 44 includes a flame retardant additive. In some embodiments, the flame retardant additive may be clays, nanoclays, silicas, carbon black, metal hydroxides such as aluminum hydroxide and aluminum trihydroxide (ATH), metal foils, graphite, and combinations thereof.

In some embodiments, the backsheet 44 forms the headlap portion 16. In some embodiments, the backsheet 44 forms the first side lap 22.

In some embodiments, the second adhesive layer 54 may include polyvinyl butyrate, acrylic, silicone, or polycarbonate. In some embodiments, the second adhesive layer 54 may include pressure sensitive adhesives. In some embodiments, the second adhesive layer 54 is composed of thermosetting polyolefin, thermosetting polyolefin encapsulant material, thermosetting ethylene-vinyl acetate (EVA), EVA encapsulants, thermoplastic olefin, thermoplastic polyolefin (TPO) or hybrids/combinations thereof.

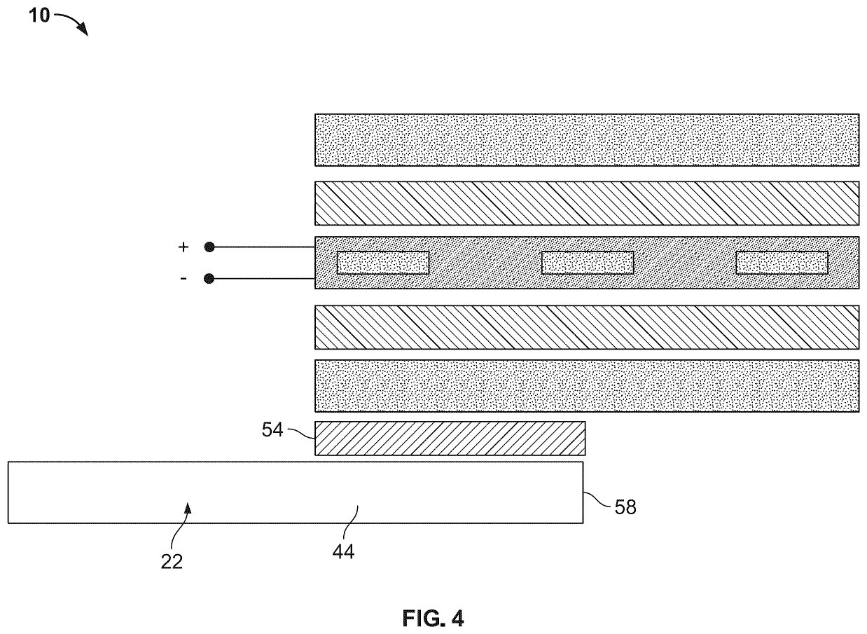

In some embodiments, the backsheet 44 includes a first end 56 and a second end 58 opposite the first end 56. Referring to FIG. 2, in some embodiments, the second end 58 of the backsheet 44 is substantially aligned with the second end 38b of the first glass layer 38 and the second end 41b of the second glass layer 41. Referring to FIG. 4, in some embodiments, the second end 58 of the backsheet 44 is between the first end 38a and the second end 38b of the first glass layer 38 and between the first end 41a and the second end 41b of the second glass layer 41.

In some embodiments, the first end 31a of the first electrical conductor 31 is between the first end 56 and the second end 58 of the backsheet 44. In some embodiments, the first end 31a of the first electrical conductor 31 is located above the first side lap 22. In some embodiments, the first end 33a of the second electrical conductor 33 is between the first end 56 and the second end 58 of the backsheet 44. In some embodiments, the first end 33a of the second electrical conductor 33 is located above the first side lap 22. In some embodiments, the first electrical conductor 31 and the second electrical conductor 33 are electrically insulated by the first side lap 22.

In some embodiments, each of the encapsulant 30, the frontsheet 36, including each of the first glass layer 38, the second glass layer 41, the polymer layer 40, and the first adhesive layer 42, the backsheet 44, and the second adhesive layer 54 of the photovoltaic shingle 10, as applicable, includes a structure, composition and/or function of similar to those of more or one of the embodiments of the corresponding or similar components disclosed in PCT International Patent Publication No. WO 2022/051593, Application No. PCT/US2021/049017, published Mar. 10, 2022, entitled Building Integrated Photovoltaic System, owned by GAF Energy LLC, the contents of which are incorporated by reference herein in its entirety.

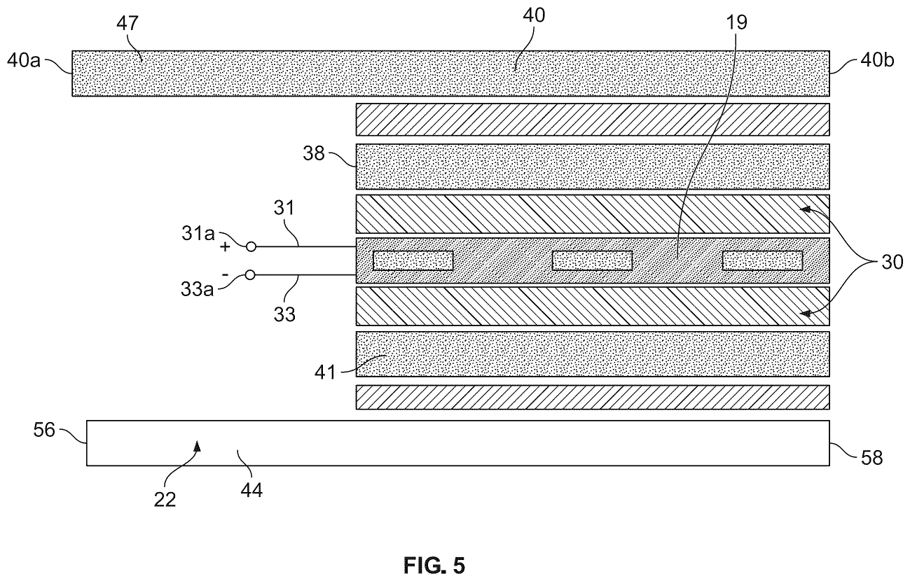

Referring to FIG. 5, in some embodiments, the polymer layer 40 includes an extended portion 47. In some embodiments, the polymer layer 40 has a length that is greater than the length of the first glass layer 38. In some embodiments, the polymer layer 40 has a length that is greater than the length of the second glass layer 41. In some embodiments, the polymer layer 40 has a length that is greater than the length of the photovoltaic layer 19. In some embodiments, the polymer layer 40 has a length that is greater than the length of the encapsulant 30. In some embodiments, the first end 40a of the polymer layer 40 is substantially aligned with the first end 56 of the backsheet 44. In some embodiments, the first end 40a of the polymer layer 40 is aligned with the first end 56 of the backsheet 44. In some embodiments, the first end 31a of the first electrical conductor 31 is between the first end 40a and the second end 40b of the polymer layer 40. In some embodiments, the first end 31a of the first electrical conductor 31 is located between the extended portion 47 of the polymer layer 40 and the first side lap 22. In some embodiments, the first end 33a of the second electrical conductor 33 is between the first end 40a and the second end 40b of the polymer layer 40. In some embodiments, the first end 33a of the second electrical conductor 33 is located between the extended portion 47 of the polymer layer 40 and the first side lap 22. In some embodiments, the first electrical conductor 31 and the second electrical conductor 33 are electrically insulated between the extended portion 47 of the polymer layer 40 and the first side lap 22.

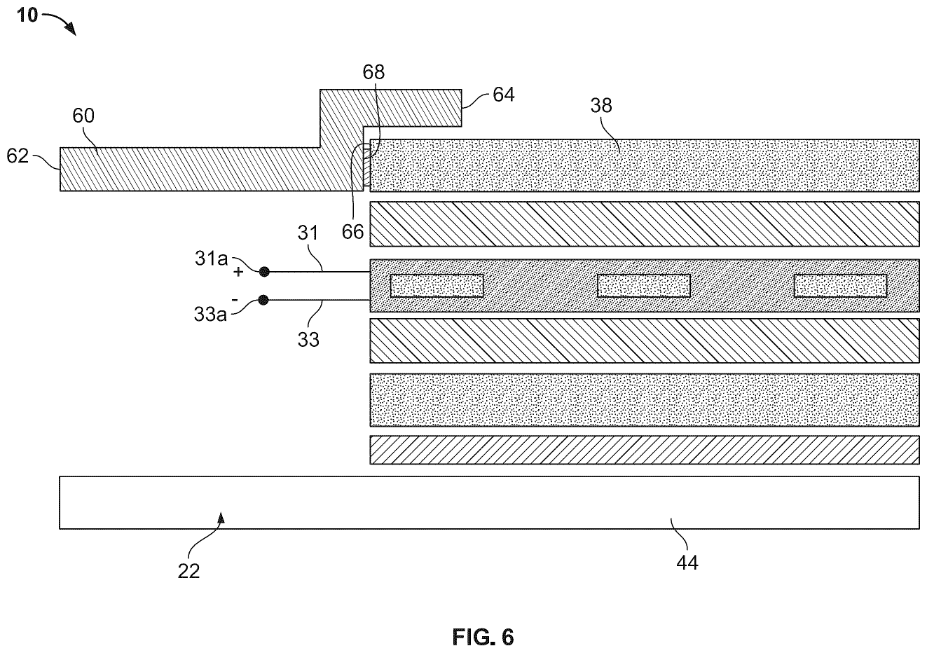

Referring to FIG. 6, in some embodiments, the photovoltaic shingle includes a bracket 60. In some embodiments, the bracket 60 includes a first end 62 and a second end 64 opposite the first end 62. In some embodiments, the second end 64 of the bracket 60 is attached to a first end 66 of the first glass layer 38. In some embodiments, the second end 64 of the bracket 60 is removably attached to a first end 66 of the first glass layer 38. In some embodiments, the bracket 60 is attached to the first glass layer by an adhesive 68. In some embodiments, the first end 31a of the first electrical conductor 31 is between the first end 62 of the bracket 60 and the first end 66 of the first glass layer 38. In some embodiments, the first end 31a of the first electrical conductor 31 is located between the bracket 60 and the first side lap 22. In some embodiments, the first end 33a of the second electrical conductor 33 is between the first end 62 of the bracket 60 and the first end 66 of the first glass layer 38. In some embodiments, the first end 33a of the second electrical conductor 33 is located between the bracket 60 and the first side lap 22. In some embodiments, the bracket 60 is made from an electrical insulating material. In some embodiments, the bracket 60 is composed of a polymer. In some embodiments, the first electrical conductor 31 and the second electrical conductor 33 are electrically insulated between the bracket 60 and the first side lap 22.

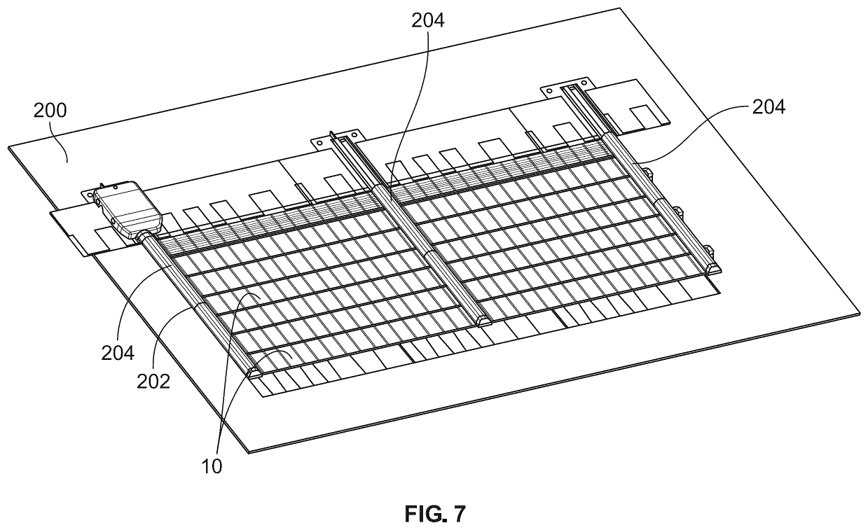

Referring to FIG. 7, in some embodiments, a roofing system includes a plurality of the photovoltaic shingles 10 installed on a roof deck 200. In some embodiments, the plurality of photovoltaic shingles 10 is installed directly to the roof deck 200. In some embodiments, each of the plurality of photovoltaic shingles 10 is installed on the roof deck 200 by a plurality of fasteners. In some embodiments, the plurality of fasteners are installed through the headlap portion 16. In some embodiments, the plurality of fasteners includes a plurality of nails. In some embodiments, the plurality of fasteners includes a plurality of rivets. In some embodiments, the plurality of fasteners includes a plurality of screws. In some embodiments, the plurality of fasteners includes a plurality of staples.

In some embodiments, each of the plurality of photovoltaic shingles 10 is installed on the roof deck 200 by an adhesive. In some embodiments, the adhesive is adhered directly to the roof deck 200. In some embodiments, the adhesive is adhered to an underlayment 202. In some embodiments, the underlayment 202 is adhered directly to the roof deck 200. In some embodiments, the adhesive is located on a rear surface of the photovoltaic shingle 10. In some embodiments, the adhesive includes at least one adhesive strip. In some embodiments, the adhesive includes a plurality of adhesive strips. In some embodiments, the plurality of adhesive strips is arranged intermittently. In some embodiments, the adhesive is located proximate to one edge of the photovoltaic shingle 10. In some embodiments, the adhesive is a peel and stick film sheet. In some embodiments, the peel and stick film sheet includes at least one sheet of film removably attached to the rear surface. In some embodiments, the peel and stick film sheet is composed of EverGuard Freedom HW peel and stick membrane manufactured by GAF. In some embodiments, the adhesive includes polyvinyl butyrate, acrylic, silicone, or polycarbonate. In some embodiments, the adhesive includes pressure sensitive adhesives.

In some embodiments, the roofing system includes at least one wireway 204. In some embodiments, the roofing system includes a plurality of wireways 204. In some embodiments, one or more of the plurality of wireways 204 includes one or more of the electrical and electronic components. In some embodiments, one or more of the plurality of wireways 204 includes an optimizer. In some embodiments, one or more of the wireways 204 includes a structure, composition, components, and/or function similar to those of one or more embodiments of the wireways disclosed in U.S. patent Application Publication No. 2023/0258369, Application Ser. No. 18/165,535, published Aug. 17, 2023, entitled Building Integrated Photovoltaic System, owned by GAF Energy LLC, the contents of which are incorporated by reference herein in its entirety.

What is claimed is:

1. A system, comprising:
a plurality of photovoltaic shingles installed on a roof deck, wherein each of the photovoltaic shingles includes
a photovoltaic layer, wherein the photovoltaic layer includes
at least one solar cell,
a first end, and
at least one electrical conductor,
wherein the at least one electrical conductor is electrically connected to the at least one solar cell,
wherein the at least one electrical conductor extends from the first end, and
wherein the at least one electrical conductor includes a first end;
an encapsulant encapsulating the at least one solar cell,
wherein the encapsulant includes a first surface and a second surface opposite the first surface,
a frontsheet juxtaposed with the first surface of the encapsulant,
wherein the frontsheet includes
a first glass layer; and
a backsheet under the second surface of the encapsulant,
wherein the backsheet includes a first end and a second end opposite the first end of the backsheet, and
wherein the first end of the at least one electrical conductor is between the first end of the backsheet and the second end of the backsheet.

2. The system of claim 1, wherein each of the plurality of photovoltaic shingles includes a second glass layer, wherein the second glass layer is between the second surface of the encapsulant and the backsheet.

3. The system of claim 1, wherein the backsheet is composed of a polymer.

4. The system of claim 3, wherein the backsheet is composed of thermoplastic polyolefin (TPO).

5. The system of claim 1, wherein the backsheet includes asphalt.

6. The system of claim 2, wherein each of the plurality of photovoltaic shingles includes a first adhesive layer, wherein the backsheet is attached to the second glass layer by the first adhesive layer.

7. The system of claim 1, wherein the frontsheet includes a polymer layer having a first surface and a second surface opposite the first surface of the polymer layer, wherein the second surface of the polymer layer is attached to the first glass layer.

8. The system of claim 7, wherein the polymer layer includes a first end and a second end opposite the first end of the polymer layer, and wherein the first end of the at least one electrical conductor is between the first end of the polymer layer and the second end of the polymer layer.

9. The system of claim 8, wherein the first end of the polymer layer is substantially aligned with the first end of the backsheet.

10. The system of claim 7, wherein the polymer layer includes ethylene tetrafluoroethylene (ETFE).

11. The system of claim 1, wherein the at least one solar cell is a tandem solar cell.

12. The system of claim 11, wherein the at least one electrical conductor includes a plurality of electrical conductors.

13. The system of claim 12, wherein the tandem solar cell is a two-conductor tandem solar cell, and wherein the plurality of electrical conductors includes two electrical conductors.

14. The system of claim 13, wherein the tandem solar cell is a four-conductor tandem solar cell, and wherein the plurality of electrical conductors includes four electrical conductors.

15. The system of claim 1, wherein each of the plurality of photovoltaic shingles includes a bracket having a first end and a second end opposite the first end of the bracket, and wherein the first glass layer includes a first end, wherein the second end of the bracket is attached to the first end of the first glass layer.

16. The system of claim 15, wherein the first end of the at least one electrical conductor is between the first end of the bracket and the first end of the first glass layer.

17. The system of claim 16, wherein the bracket is attached to the first glass layer by an adhesive.

18. The system of claim 17, wherein the bracket is made from an electrical insulating material.

19. The system of claim 2, wherein each of the first glass layer and the second glass layer has a thickness of 0.5 mm to 3 mm.

20. A photovoltaic shingle, comprising:
a photovoltaic layer, wherein the photovoltaic layer includes
at least one solar cell,
a first end, and
at least one electrical conductor,
wherein the at least one electrical conductor is electrically connected to the at least one solar cell,
wherein the at least one electrical conductor extends from the first end, and
wherein the at least one electrical conductor includes a first end;
an encapsulant encapsulating the at least one solar cell,
wherein the encapsulant includes a first surface and a second surface opposite the first surface,
a frontsheet juxtaposed with the first surface of the encapsulant,
wherein the frontsheet includes
a first glass layer; and
a backsheet under the second surface of the encapsulant,
wherein the backsheet includes a first end and a second end opposite the first end of the backsheet, and
wherein the first end of the at least one electrical conductor is between the first end of the backsheet and the second end of the backsheet.
